(19) United States
(12) Patent Application Publication
(10) Pub. No.: US 2026/0266970 A1
(43) Pub. Date: Sep. 10, 2026

(54) ENHANCING LASER SAFETY OF TIME OF FLIGHT (ToF) SENSOR IN EXTENDED REALITY (XR) DEVICES

(71) Applicant: QUALCOMM Incorporated, San Diego, CA (US)

(72) Inventors: Sukumar SAMAL, Tellapur (IN); Manoj ALLADA, Hyderabad (IN); Subbarami Reddy GOTTIGUNDALA, Hyderabad (IN); Thirukumaran DECHINAMOORTHY, Hyderabad (IN)

(21) Appl. No.: 19/024,633

(22) Filed: Jan. 16, 2025

(51) Int. Cl. G01S 7/497; G01R 31/26; G01S 7/481; G01S 7/4865

(52) U.S. Cl. CPC G01S 7/497; G01R 31/2601; G01S 7/4811; G01S 7/4865

(57) ABSTRACT

Aspects of the disclosure are directed to enhancing laser safety of time of flight (ToF) sensors. In accordance with one aspect, the disclosure includes a cover glass including a first surface and a second surface; a conductive coating on the first surface of the cover glass; a pulldown resistor connected electrically in series to the conductive coating; and an analog to digital converter (ADC) electrically connected to the conductive coating.

### TECHNICAL FIELD

This disclosure relates generally to the field of laser safety, and, in particular, to enhancing a laser safety of time of flight (ToF) sensor for extended reality (XR) devices.

### BACKGROUND

A time of flight (ToF) sensor using a laser source has utility in extended reality (XR) devices for three-dimensional (3D) imaging and depth sensing. However, the high spatial and temporal coherence of the laser source results in a high radiant power density (W/m²) or high radiant energy density (J/m²) level which may exceed eye and skin safety thresholds. The ToF sensor may employ a cover glass as a protection mechanism. There is a need for a reliable detector for ensuring the integrity of the cover glass to ensure human safety.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In one aspect, the disclosure provides enhancing laser safety of time of flight (ToF) sensors. Accordingly, the present disclosure discloses a method including: measuring a monitor voltage related to a voltage divider at a cover glass coating terminal; comparing the monitor voltage to a voltage threshold setting; determining if the monitor voltage exceeds the voltage threshold setting; and declaring a conductive fault condition in a cover glass of a laser time of flight (ToF) sensor.

In one example, the method further includes delivering a monitor voltage to a conductive coating, wherein the conductive coating is in series with a pulldown resistor connected to a common electrical ground. In one example, the pulldown resistor has a resistance greater than that of the conductive coating. In one example, the conductive coating is applied on the cover glass of the laser ToF sensor. In one example, the monitor voltage is measured with respect to the common electrical ground. In one example, the method further includes configuring the voltage threshold setting. In one example, the voltage threshold setting represents a detection level for a fault in electrical conductivity in the cover glass. In one example, the conductive fault condition is a result of a physical breakage in the cover glass. In one example, the conductive fault condition is a result of an absence of the cover glass. In one example, the laser ToF sensor generates a coherent optical waveform. In one example, the laser ToF sensor receives the coherent optical waveform using a laser receiver.

Another aspect of the disclosure provides an apparatus including: a cover glass including a first surface and a second surface; a conductive anti-reflective coating on the first surface of the cover glass; a pulldown resistor connected electrically in series to the conductive anti-reflective coating; and an analog to digital converter (ADC) electrically connected to the conductive anti-reflective coating.

In one example, the apparatus further includes an electrical ground, wherein the electrical ground is electrically connected to the pulldown resistor and the ADC. In one example, the apparatus further includes an anti-reflective coating on the second surface of the cover glass. In one example, the anti-reflective coating is non-conductive. In one example, the apparatus further includes a time of flight (ToF) sensor, wherein the ToF sensor includes a laser diffuser. In one example, the cover glass covers the laser diffuser to avoid physical injury to an organism skin. In one example, the apparatus further includes a processing engine coupled to the ADC, the processing engine configured to compare a monitor voltage of the conductive anti-reflective coating to a voltage threshold setting.

Another aspect of the disclosure provides an apparatus including: means for measuring a monitor voltage related to a voltage divider at a cover glass coating terminal; means for comparing the monitor voltage to a voltage threshold setting; means for determining if the monitor voltage exceeds the voltage threshold setting; and means for declaring a conductive fault condition in a cover glass of a laser time of flight (ToF) sensor. In one example, the apparatus includes means for measuring a monitor voltage related to a current source signal at a cover glass coating terminal.

In one example, the apparatus further includes: means for delivering a monitor voltage signal to a conductive anti-reflective coating, wherein the conductive anti-reflective coating is in series with a pulldown resistor connected to a common electrical ground; and means for configuring the voltage threshold setting.

These and other aspects of the present disclosure will become more fully understood upon a review of the detailed description, which follows. Other aspects, features, and implementations of the present disclosure will become apparent to those of ordinary skill in the art, upon reviewing the following description of specific, exemplary implementations of the present invention in conjunction with the accompanying figures. While features of the present invention may be discussed relative to certain implementations and figures below, all implementations of the present invention can include one or more of the advantageous features discussed herein. In other words, while one or more implementations may be discussed as having certain advantageous features, one or more of such features may also be used in accordance with the various implementations of the invention discussed herein. In similar fashion, while exemplary implementations may be discussed below as device, system, or method implementations it should be understood that such exemplary implementations can be implemented in various devices, systems, and methods.

### BRIEF DESCRIPTION OF THE DRAWINGS

FIG. 1 illustrates an example laser time of flight (ToF) sensor.

FIG. 2 illustrates an example laser time of flight (ToF) sensor cover glass design.

FIG. 3 illustrates an example laser time of flight (ToF) sensor system.

FIG. 4 illustrates an example head mounted device (HMD) laser time of flight (ToF) sensor system.

FIG. 5 illustrates a first example laser time of flight (ToF) sensor application.

FIG. 6 illustrates a second example laser time of flight (ToF) sensor application.

FIG. 7 illustrates an example flow diagram for enhancing laser safety of time of flight (ToF) sensor for extended reality (XR) devices.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

While for purposes of simplicity of explanation, the methodologies are shown and described as a series of acts, it is to be understood and appreciated that the methodologies are not limited by the order of acts, as some acts may, in accordance with one or more aspects, occur in different orders and/or concurrently with other acts from that shown and described herein. In one example, an extended reality (XR) system may incorporate a laser ToF sensor for 3D imaging and depth sensing. The laser ToF sensor may be a concern for eye and skin safety and thus some form of protection is needed. For example, a regulatory document, IEC 60825-1:2024 Laser Safety Standard, mandates that a laser ToF sensor incorporate a cover glass for laser safety. In one example, the cover glass protects a laser diffuser in the laser ToF sensor and prevents direct contact to protect the skin (i.e., an organism skin). For example, the cover glass protects the laser diffuser from physical damage to avoid eye and skin injuries and environmental harm.

Relative distance between two positions may be obtained by measuring a round-trip propagation time or a time of flight (ToF) of some type of energy transmission. Time of flight (ToF) and distance may be related using a ToF sensor knowing a propagation speed of the energy transmission. A ToF sensor relies on electromagnetic or acoustic radiant energy to illuminate a designated target at a range R and to determine the range R from a round-trip time delay T measurement. For example, time of flight is equal to the round-trip time delay T. In one example, the ToF sensor relies on a fundamental physical relationship between round-trip time delay T, in seconds(s), and range R, in meters (m), via:

R=cT/2; where c=propagation speed in m/s.

For example, there is a range R of 149.9 m per microsecond of round-trip time delay for electromagnetic propagation in a free space medium (i.e., where c=299 792 458 m/s).

One type of a ToF sensor is a laser ToF sensor. The laser ToF sensor uses a laser source to generate a coherent optical waveform to illuminate a designated target and uses a laser receiver to determine its distance from the laser ToF sensor. In one example, the coherent optical waveform has high local correlation in the spatial domain or in the temporal domain or in both domains. In one example, the coherent optical waveform is a form of electromagnetic radiant energy using optical wavelengths (i.e., infrared, visible or ultraviolet wavelengths).

In one example, the XR system may not have a safety mechanism to detect cover glass integrity or actual presence. For example, a user may not be aware of potential laser risks and may use the XR system with a damaged cover glass or without an intact cover glass resulting in laser hazard exposure.

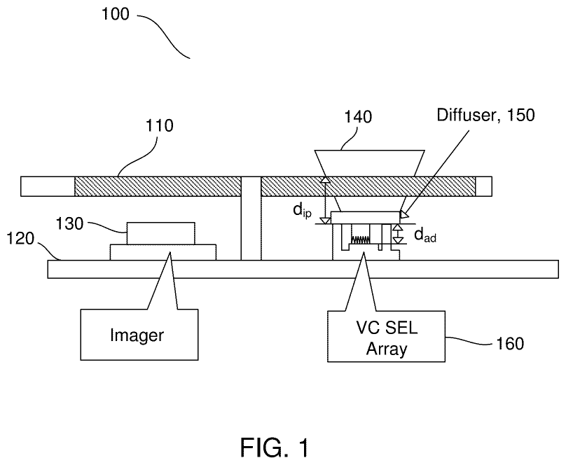

FIG. 1 illustrates an example laser time of flight (ToF) sensor 100. In one example, the laser ToF sensor 100 includes a cover glass 110, a mounting structure 120 which hosts an imager 130 and a laser diode array 160, a diffuser 150 and a diffused laser beam 140. In one example, the mounting structure 120 is a printed circuit board (PCB) or a printed wiring board (PWB). In one example, the laser diode array 160 is a vertical cavity surface emitting laser (VCSEL) array. For example, the laser diode array 160 may serve as a laser source to generate the diffused laser beam 140 for transmission to an intended target. For example, the laser source generates the diffused laser beam 140 with an optical wavelength (i.e., a wavelength from the infrared, visible or ultraviolet spectrum). For example, the imager 130 may serve as a laser receiver to capture a reflected optical waveform from the intended target. In one example, FIG. 1 also denotes a distance dip between the diffuser 150 and a top side of the cover glass 110 and a distance dad between the diffuser 150 and the laser diode array 160.

In one example, a cover glass used in a laser ToF sensor may include an anti-reflective, non-conductive coating to attain a high transmittivity (i.e., a high throughput between input and output). However, usage of the anti-reflective, non-conductive coating inhibits a capability for determine cover glass integrity. In one example, the conductive coating is a conductive anti-reflective coating.

In one example, a cover glass may instead use an anti-reflective, conductive coating to determine cover glass integrity. In one example, the cover glass may use magnesium fluoride (MgF2) or indium tin oxide (ITO). In one example, the cover glass may be optically transparent (i.e., transparent over optical wavelengths ranging from infrared wavelengths to ultraviolet wavelengths). In one example, the cover glass may be coupled to electrical circuitry for detection of cover glass integrity. In one example, cover glass integrity includes presence of the cover glass, and the electrical circuitry includes a notification capability for a need for corrective action during device initialization due to accidental damage of the cover glass. In one example, conductive refers to an electrical property of substantial current flow for a given voltage.

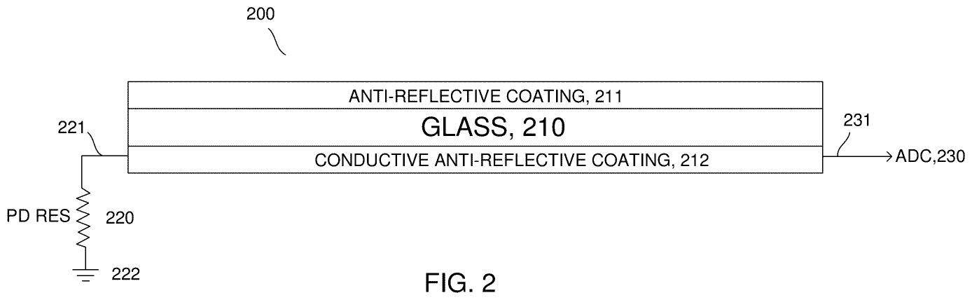

FIG. 2 illustrates an example laser time of flight (ToF) sensor cover glass design 200. In one example, the laser ToF sensor cover glass design 200 includes a cover glass 210 with an anti-reflective coating 211 on a first side and a conductive anti-reflective coating 212 on a second side. In one example, a first terminal 221 of the conductive anti-reflective coating 212 is connected to a pulldown resistor (PD Res) 220 which in turn is connected to electrical ground 222. In one example, a second terminal 231 of the conductive anti-reflective coating 212 is connected to an analog to digital converter (ADC) 230. In one example, the ADC 230 converts a voltage level of the conductive anti-reflective coating 212 to a digital sample.

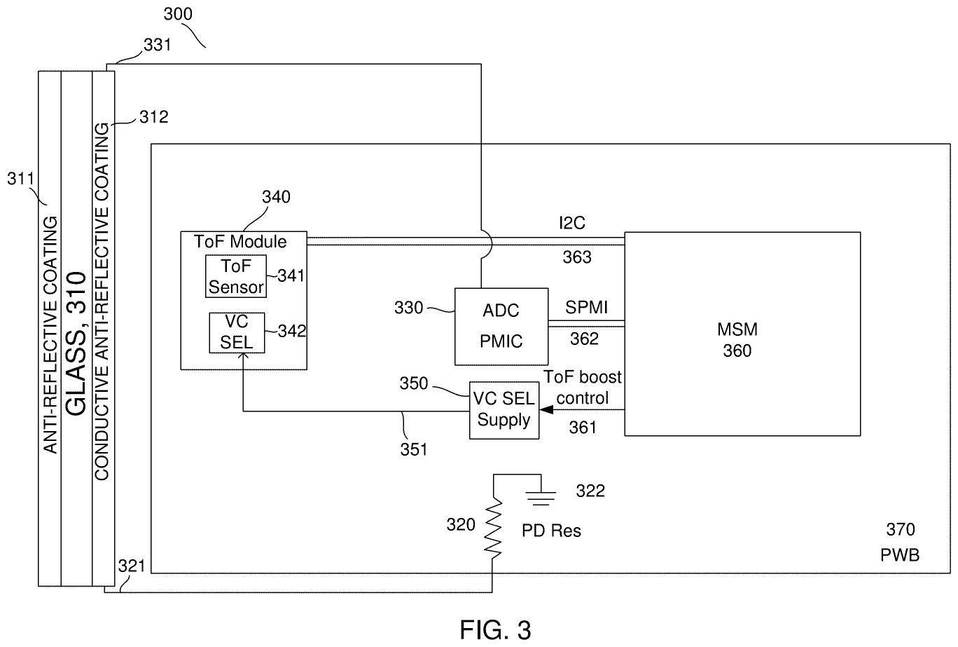

FIG. 3 illustrates an example laser time of flight (ToF) sensor system 300. In one example, the laser ToF sensor system 300 includes a cover glass 310 with an anti-reflective coating 311 on a first side and a conductive anti-reflective coating 312 on a second side. As an example, FIG. 3 shows the cover glass 310 located between the anti-reflective coating 311 and the conductive anti-reflective coating 312.

In one example, a first terminal 321 of the conductive anti-reflective coating 312 is connected to a pulldown (PD) resistor 320 which in turn is connected to electrical ground 322. In one example, a second terminal 331 of the conductive anti-reflective coating 312 is connected to a power management integrated circuit (PMIC) 330 with an analog to digital converter (ADC). Alternatively, the ADC may be located in a microcontroller (not shown). In one example, the ADC in PMIC 330 converts a voltage level of the conductive anti-reflective coating 312 to a digital sample. In one example, the PD resistor 330 has a resistance between 1 kohm and 1 Megaohm. In one example, the ADC in PMIC 330 employs a voltage divider circuit at the ADC input with the PD resistor 330 tied to ground 322 and an internal pull up resistor (not shown) tied to a positive drain voltage V_{DD}. In one example, the internal pull up resistor has a nominal value of 100 Kohm.

In one example, the laser ToF sensor system 300 also includes a ToF module 340 with a ToF sensor 341 and a laser diode array 342. In one example, the ToF sensor 341 is a laser ToF sensor. In one example, the ToF sensor 341 includes a laser receiver to capture a reflected optical waveform from an intended target. In one example, the laser diode array 342 is a vertical cavity surface emitting laser (VCSEL) array. In one example, the laser diode array 342 serves as a laser source to generate a coherent optical waveform for transmission to the intended target. In one example, a laser diode array power supply 350 (e.g., voltage regulator) provides a dc voltage level 351 to the ToF module 340. In one example, a modem 360 is coupled to the ToF module 340 via an inter-integrated circuit (I2C) interface 363. In one example, the modem 360 is coupled to PMIC 330 via a system power management interface (SPMI) 362. In one example, the modem 360 provides a ToF boost control signal 361 to the laser diode array power supply 350. In one example, the ToF boost control signal 361 enables the laser diode array power supply 350.

In one example, the pulldown resistor 320, the PMIC 330, the ToF module 340, the laser diode array power supply 350 and the modem 360 are mounted onto a printed wiring board (PWB) 370.

In one example, upon power initialization, the PMIC 330 measures a monitor voltage at the second terminal 331 and compares the monitor voltage to a nominal voltage range. In one example, if the monitor voltage is within the nominal voltage range, the PMIC 330 proceeds with power initialization. In one example, if the monitor voltage is outside the nominal voltage range (i.e., either higher or lower than the nomina voltage range), the PMIC 330 detects a cover glass fault and halts the power initialization with a laser safety warning indication on a display. In one example, the cover glass fault may be due to a missing cover glass or a damaged cover glass. In one example, the nominal voltage range is preassigned to define nominal scenarios with positive cover glass integrity (i.e., correct voltage levels without damaged or missing cover glass).

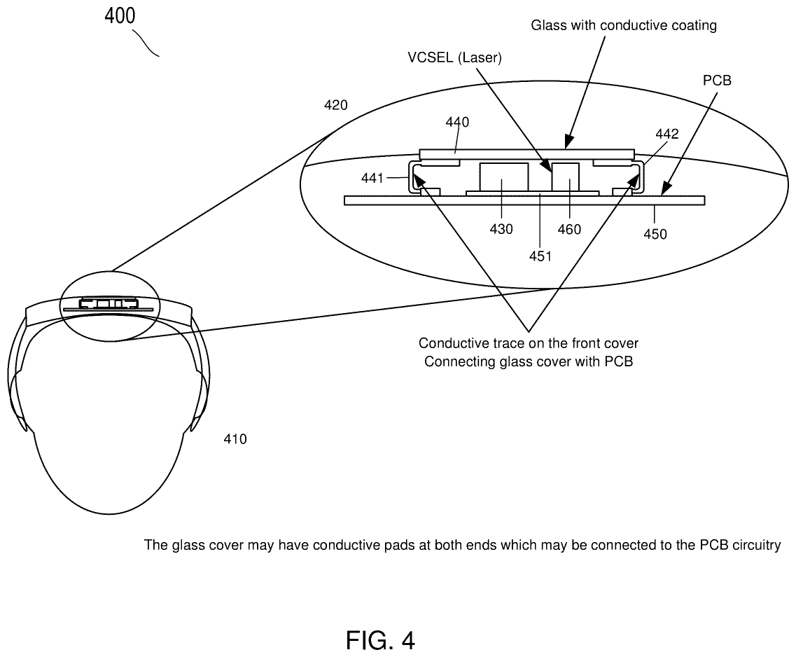

FIG. 4 illustrates an example head mounted device (HMD) laser time of flight (ToF) sensor system 400. In one example, the HMD laser ToF sensor system 400 includes a HMD 410 and a laser ToF sensor 420. In one example, the laser ToF sensor 420 includes an imager 430 and a laser diode array 460 mounted onto a substrate 451. In one example, the laser ToF sensor 420 includes a conductive cover glass 440 and a mounting structure 450. In one example, the mounting structure 450 may be a printed circuit board (PCB) or a printed wiring board (PWB).

In one example, a first terminal of the conductive cover glass 440 is connected to a pulldown (PD) resistor (not shown) which in turn is connected to an electrical ground (not shown). In one example, a second terminal of the conductive cover glass 440 is connected to an analog to digital converter (ADC) (not shown). In one example, the ADC converts a voltage level of the conductive cover glass 440 to a digital sample. In one example, the PD resistor has a resistance ranging between 1 kohm and 1 Megaohm. In one example, the ADC may be positioned onto the mounting structure 450. In one example, the ADC may be part of another circuit, e.g., a PMIC (not shown).

In one example, a first conductive trace 441 and a second conductive trace 442 connect the conductive cover glass 440 with the mounting structure 450. In one example, the first conductive trace 441 and the second conductive trace 442 are on opposite ends of the conductive cover glass 440.

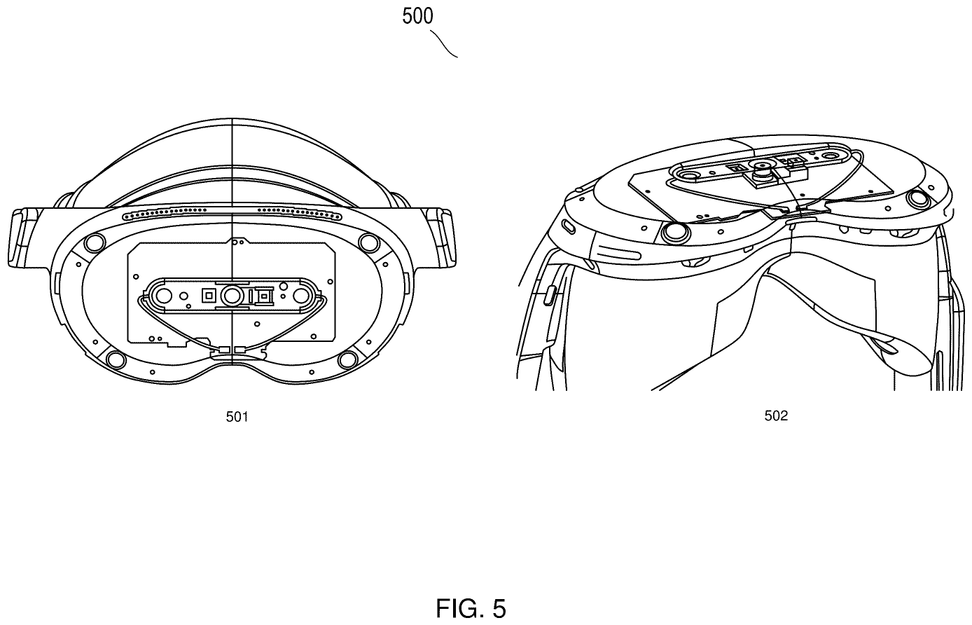

FIG. 5 illustrates a first example laser time of flight (ToF) sensor application 500. In one example, the first laser ToF sensor application 500 is an extended reality (XR) headset with a laser ToF sensor. In one example, the first example laser ToF sensor application 500 includes a front view 501 and perspective bottom/side view 502. In one example, the front view 501 shows an extended reality (XR) headset 510 and a laser ToF sensor 520. In one example, the perspective bottom/side view also shows the extended reality (XR) headset 510 and the laser ToF sensor 520.

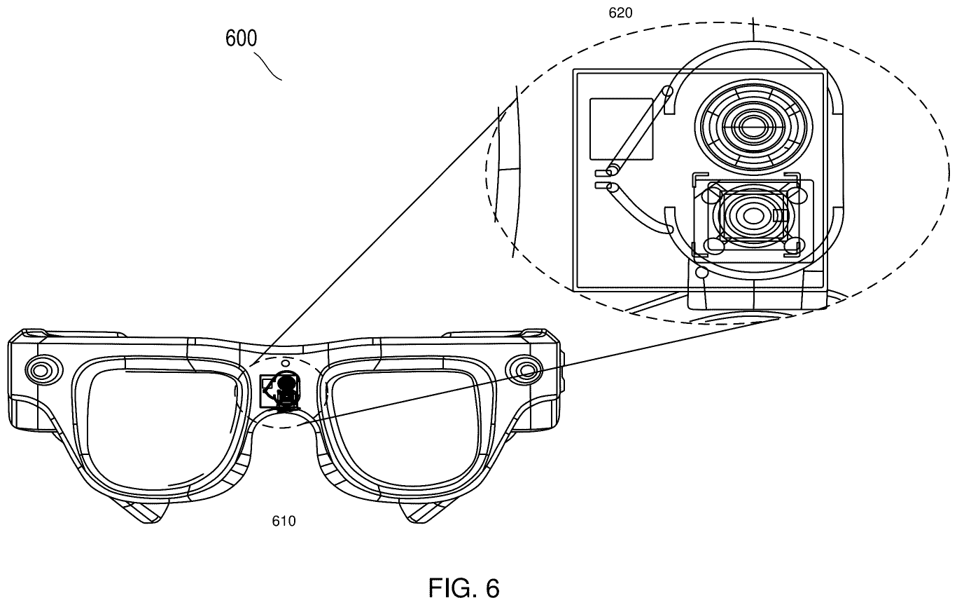

FIG. 6 illustrates a second example laser time of flight (ToF) sensor application 600. In one example, the second laser ToF sensor application 600 is an extended reality (XR) smart glasses with a laser ToF sensor. In one example, the second laser ToF sensor application 600 shows an extended reality (XR) smart glasses 610 and a laser ToF sensor 620.

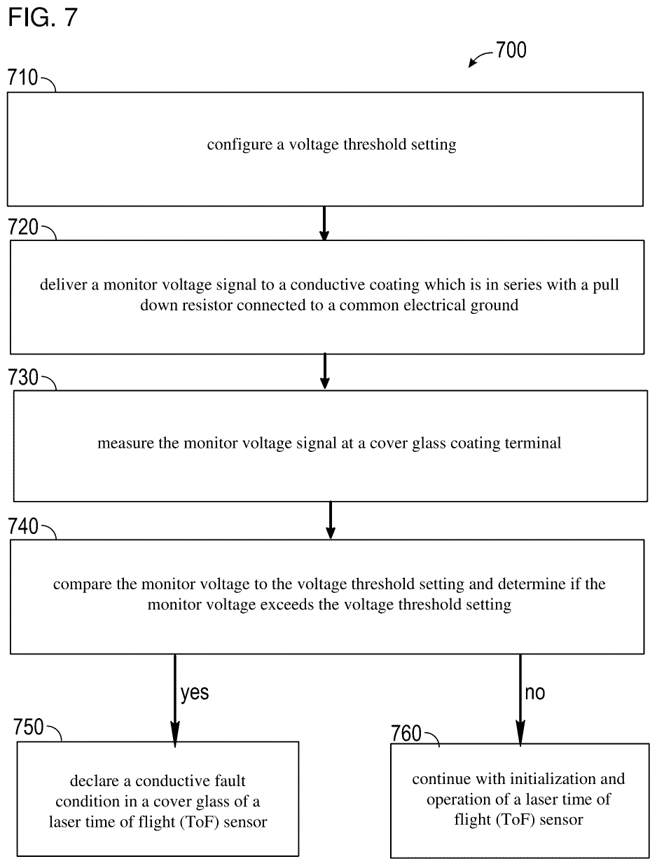

FIG. 7 illustrates an example flow diagram 700 for enhancing laser safety of time of flight (ToF) sensor for extended reality (XR) devices. In block 710, configure a voltage threshold setting. In one example, a voltage threshold setting. is configured, for example, by selecting a numerical value into a databus. In one example, the voltage threshold setting is for determining a conductive fault condition in a laser time of flight (ToF) sensor. In one example, the laser ToF sensor generates a coherent optical waveform. In one example, the laser ToF sensor receives the coherent optical waveform using a laser receiver. In one example, the laser receiver is a photodetector. In one example, the voltage threshold setting is greater than a nominal voltage level. In one example, the voltage threshold setting exceeds the nominal voltage level by a predetermined fractional value (e.g., percentage of the nominal voltage level). In one example, the nominal voltage level is an expected voltage level with no conductive fault condition. In one example, the step of block 710 is performed by a processing engine, a microcontroller, a microprocessor, a system on a chip (SoC), a central processing unit (CPU), etc.

In block 720, deliver a monitor voltage signal to a conductive coating which is in series with a pulldown resistor connected to a common electrical ground. In one example, the monitor voltage signal is delivered to a conductive coating which is in series with a pulldown resistor connected to a common electrical ground. In one example, the pulldown resistor has a resistance greater than that of the cover glass conductive coating. In one example, the cover glass conductive coating is applied on a cover glass of the laser ToF sensor. In one example, the step of block 720 is performed by a power management integrated circuit (PMIC), or by an analog to digital converter (ADC), etc.

In block 730, measure the monitor voltage signal at a cover glass coating terminal. In one example, the monitor voltage signal at the cover glass coating terminal is measured. In one example, the monitor voltage is measured with respect to the common electrical ground. In one example, the monitor voltage may be measured with an analog to digital converter (ADC). In one example, the ADC may be part of a power management integrated circuit (PMIC) in the ToF sensor. In one example, the monitor voltage signal is measured using a voltage divider. In one example, the step of block 730 is performed by a digital multimeter, an analog to digital converter (ADC), etc.

In block 740, compare the monitor voltage to the voltage threshold setting and determine if the monitor voltage exceeds the voltage threshold setting. In one example, the monitor voltage is compared to the voltage threshold setting and determine if the monitor voltage exceeds the voltage threshold setting. In one example, the comparison of the monitor voltage to the voltage threshold setting is to determine a conductive fault condition in the cover glass of the laser ToF sensor. In one example, the voltage threshold setting represents a detection level for a fault in electrical conductivity in the cover glass. In one example, the step of block 740 is performed by a processing engine, a microcontroller, a microprocessor, a system on a chip (SoC), a central processing unit (CPU), etc.

In block 750, if the monitor voltage exceeds the voltage threshold setting, then declare a conductive fault condition in a cover glass of a laser time of flight (ToF) sensor. In one example, a conductive fault condition in a cover glass of a laser time of flight (ToF) sensor is declared. In one example, the conductive fault condition is due to (i.e., the result of) a physical breakage in the cover glass. In one example, the conductive fault condition is due to (i.e., the result of) an absence of the cover glass. In one example, the step of block 750 is performed by a processing engine, a microcontroller, a microprocessor, a system on a chip (SoC), a central processing unit (CPU), etc.

In block 760, if the monitor voltage does not exceed the voltage threshold setting, then continue with initialization and operation of a laser time of flight (ToF) sensor. In one example, initialization and operation of a laser time of flight (ToF) sensor is continued. In one example, the initialization and operation of the laser ToF sensor provides time of flight (ToF) measurements to determine a relative distance. In one example, the step of block 760 is performed by a processing engine, a microcontroller, a microprocessor, a system on a chip (SoC), a central processing unit (CPU), etc.

In one aspect, one or more of the steps for providing enhancing laser safety of a time of flight (ToF) sensor in FIG. 7 may be executed by one or more processors which may include hardware, software, firmware, etc. The one or more processors, for example, may be used to execute software or firmware needed to perform the steps in the flow diagram of FIG. 7. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise.

The software may reside on a computer-readable medium. The computer-readable medium may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium may also include, by way of example, a carrier wave, a transmission line, and any other suitable medium for transmitting software and/or instructions that may be accessed and read by a computer. The computer-readable medium may reside in a processing system, external to the processing system, or distributed across multiple entities including the processing system. The computer-readable medium may be embodied in a computer program product. By way of example, a computer program product may include a computer-readable medium in packaging materials. The computer-readable medium may include software or firmware. Those skilled in the art will recognize how best to implement the described functionality presented throughout this disclosure depending on the particular application and the overall design constraints imposed on the overall system.

Any circuitry included in the processor(s) is merely provided as an example, and other means for carrying out the described functions may be included within various aspects of the present disclosure, including but not limited to the instructions stored in the computer-readable medium, or any other suitable apparatus or means described herein, and utilizing, for example, the processes and/or algorithms described herein in relation to the example flow diagram.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

One skilled in the art would understand that various features of different embodiments may be combined or modified and still be within the spirit and scope of the present disclosure.

What is claimed is:

1. A method comprising:
measuring a monitor voltage related to a voltage divider at a cover glass coating terminal;
comparing the monitor voltage to a voltage threshold setting;
determining if the monitor voltage exceeds the voltage threshold setting; and
declaring a conductive fault condition in a cover glass of a laser time of flight (ToF) sensor.

2. The method of claim 1 further comprising delivering a monitor voltage signal to a conductive coating, wherein the conductive coating is in series with a pulldown resistor connected to a common electrical ground.

3. The method of claim 2, wherein the pulldown resistor has a resistance greater than that of the conductive coating.

4. The method of claim 2, wherein the conductive coating is applied on the cover glass of the laser ToF sensor.

5. The method of claim 4, wherein the monitor voltage is measured with respect to the common electrical ground.

6. The method of claim 5 further comprising configuring the voltage threshold setting.

7. The method of claim 6, wherein the voltage threshold setting represents a detection level for a fault in electrical conductivity in the cover glass.

8. The method of claim 7, wherein the conductive fault condition is a result of a physical breakage in the cover glass.

9. The method of claim 7, wherein the conductive fault condition is a result of an absence of the cover glass.

10. The method of claim 6, wherein the laser ToF sensor generates a coherent optical waveform.

11. The method of claim 10, wherein the laser ToF sensor receives the coherent optical waveform using a laser receiver.

12. An apparatus comprising:
a cover glass including a first surface and a second surface;
a conductive anti-reflective coating on the first surface of the cover glass;
a pulldown resistor connected electrically in series to the conductive anti-reflective coating; and
an analog to digital converter (ADC) electrically connected to the conductive anti-reflective coating.

13. The apparatus of claim 12, further comprising an electrical ground, wherein the electrical ground is electrically connected to the pulldown resistor and the ADC.

14. The apparatus of claim 13, further comprising an anti-reflective coating on the second surface of the cover glass.

15. The apparatus of claim 14, wherein the anti-reflective coating is non-conductive.

16. The apparatus of claim 13, further comprising a time of flight (ToF) sensor, wherein the ToF sensor includes a laser diffuser.

17. The apparatus of claim 16, wherein the cover glass covers the laser diffuser to avoid physical injury to an organism skin.

18. The apparatus of claim 12, further comprising a processing engine coupled to the ADC, the processing engine configured to compare a monitor voltage of the conductive anti-reflective coating to a voltage threshold setting.

19. An apparatus comprising:
means for measuring a monitor voltage related to a voltage divider at a cover glass coating terminal;
means for comparing the monitor voltage to a voltage threshold setting;
means for determining if the monitor voltage exceeds the voltage threshold setting; and
means for declaring a conductive fault condition in a cover glass of a laser time of flight (ToF) sensor.

20. The apparatus of claim 19, further comprising:
means for delivering a monitor voltage signal to a conductive coating, wherein the conductive coating is in series with a pulldown resistor connected to a common electrical ground; and
means for configuring the voltage threshold setting.
